(19) United States
(12) Patent Application Publication
(10) Pub. No.: US 2005/0051427 A1
(43) Pub. Date: Mar. 10, 2005

(54) Rolled electrode array and its method for manufacture

(76) Inventors: James H. Brauker, San Diego, CA (US); Paul V. Neale, San Diego, CA (US); Peter C. Simpson, Del Mar, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/896,637

(22) Filed: Jul. 21, 2004

Related U.S. Application Data
(60) Provisional application No. 60/489,615, filed on Jul. 23, 2003.

(51) Int. Cl. H01L 21/00; B05D 5/12

(52) U.S. Cl. 204/412; 427/58

(57) ABSTRACT

An electrode array for use in an electrochemical device is provided. The electrode array includes at least one electrode material and at least one insulating material arranged in a spiral configuration. The electrode array is manufactured by forming a composite stack of the at least one electrode material and the at least one insulating material, such that the insulating material(s) surrounds the electrode material(s) after which the stack is rolled into a spiral roll. The spiral roll can be cut, sliced, and/or dissected in numerous ways to form the electrode array of the preferred embodiments. Optionally, the sections can be further processed by machining, polishing, etching, or the like, to produce a curvature or stepped configuration.

### RELATED APPLICATION

This application claims the benefit of U.S. Provisional Application No. 60/489,615 filed Jul. 23, 2003, the contents of which are hereby incorporated by reference in their entirety.

### FIELD OF THE INVENTION

This invention relates to electrode arrays for use in electrochemical devices and their method for manufacture. The electrode arrays include one or more electrode materials surrounded by insulating material, wherein the one or more electrode materials and the insulating material are arranged in a spiral configuration.

### BACKGROUND OF THE INVENTION

Electrochemical sensors are useful in chemistry and medicine to determine the presence and concentration of a biological analyte. Such sensors are useful, for example, to monitor glucose in diabetic patients and lactate during critical care events.

Conventional electrochemical sensors use a variety of electrode and microelectrode configurations. Conventional electrode arrays are typically manufactured using techniques such as thick film printing, screen printing, lithography, letter press printing, vapor deposition, spray coating, pad printing, ink jet printing, laser jet printing, roller coating, vacuum deposition, thin film deposition, sputtering, evaporation, glow discharge methods, and the like. Conventionally, these techniques are used to deposit electrode material in a variety of configurations onto an insulating material to form the electrode array. Unfortunately, many of these techniques are time consuming and expensive. Additionally, thin films can lack in robustness, particularly in long term and potentially harsh environments experienced by many sensors. Furthermore, there are often concerns about delamination of films from the base substrate, and many thick and thin film techniques can cause contamination of the insulating material because of the formation of the electrodes.

### SUMMARY OF THE PREFERRED EMBODIMENTS

There is a need for time-efficient and inexpensive methods for manufacturing electrodes that exhibit long term robustness and which do not introduce contaminants during the manufacturing process.

Accordingly, in a first embodiment, an electrode array for use in an electrochemical device is provided, the electrode array including: a first electrode material; and an insulating material, wherein the first electrode material and the insulating material are arranged in a spiral configuration.

In an aspect of the first embodiment, a working electrode is formed from the first electrode material, and wherein the first electrode material includes a material selected from the group consisting of glassy carbon, gold, platinum, palladium, nickel, silver, copper, lead, zinc, silver/carbon, and combinations thereof.

In an aspect of the first embodiment, the first electrode material includes a sheet.

In an aspect of the first embodiment, the first electrode material includes a mesh.

In an aspect of the first embodiment, the first electrode material includes a film.

In an aspect of the first embodiment, the first electrode material includes a wire.

In an aspect of the first embodiment, the electrode array further includes a second electrode material.

In an aspect of the first embodiment, the electrode array further includes a counter electrode formed from the second electrode material, wherein the first electrode material, the insulating material, and the second electrode material are arranged in a spiral configuration, and wherein the second electrode material is selected from the group consisting of glassy carbon, gold, platinum, palladium, nickel, silver, copper, lead, zinc, silver/carbon, and combinations thereof.

In an aspect of the first embodiment, the second electrode material includes a sheet.

In an aspect of the first embodiment, the second electrode material includes a mesh.

In an aspect of the first embodiment, the second electrode material includes a film.

In an aspect of the first embodiment, the second electrode material includes a wire.

In an aspect of the first embodiment, the electrode array further includes a reference electrode.

In an aspect of the first embodiment, the first electrode material, the insulating material, and the third electrode material are arranged in a spiral configuration.

In an aspect of the first embodiment, the third electrode material includes a sheet.

In an aspect of the first embodiment, the third electrode material includes a mesh.

In an aspect of the first embodiment, the third electrode material includes a film.

In an aspect of the first embodiment, the third electrode material includes a wire.

In an aspect of the first embodiment, the reference electrode is located at a center of the spiral configuration.

In an aspect of the first embodiment, the electrode array further includes second electrode material and a third electrode material, wherein the first electrode material includes a working electrode, wherein the second electrode material includes a counter electrode, and wherein the third electrode material includes a reference electrode.

In an aspect of the first embodiment, the electrode array further includes a second electrode material and a third electrode material, wherein the first electrode material includes a first working electrode, wherein the second electrode material includes a second working electrode, and wherein the third electrode material includes a reference electrode.

In an aspect of the first embodiment, the electrode array further includes a reference electrode.

In an aspect of the first embodiment, the electrode array further includes a second electrode material and a third electrode material, wherein the first electrode material includes a first working electrode, wherein the second electrode material includes a second working electrode, and wherein the third electrode material includes a counter electrode.

In an aspect of the first embodiment, the insulating material includes a silicone or a hydrogel.

In an aspect of the first embodiment, the insulating material includes a high oxygen soluble polymer.

In an aspect of the first embodiment, the insulating material is selected from the group consisting of polyimide, polyester, polyurethane, perfluorinated polymer, polycarbonate, polyvinyl chloride, high-density polypropylene, low-density polypropylene, Parylene, epoxy, hydrogels, silicone, and mixtures thereof.

In an aspect of the first embodiment, the insulating material includes a thickness of from about 1 micron to about 1000 microns.

In an aspect of the first embodiment, the insulating material includes a thickness of from about 1 micron to about 100 microns.

In an aspect of the first embodiment, the electrode array includes a substantially planar surface.

In an aspect of the first embodiment, the electrode array includes a substantially curved surface.

In an aspect of the first embodiment, the electrode array includes a stepped surface.

In an aspect of the first embodiment, the electrode array further includes a polymer material formed atop at least one stepped surface.

In an aspect of the first embodiment, the electrode array is flexible.

In a second embodiment, a method for manufacturing an electrode array for use in an electrochemical device is provided, the method including: forming a composite stack including an electrode material and an insulating material, wherein the insulating material is situated adjacent to the electrode material; rolling the composite stack into a spiral roll; and cutting away a portion of the spiral roll to form an electrode array.

In an aspect of the second embodiment, the composite stack is formed by adhering the electrode material to the insulating material.

In an aspect of the second embodiment, the electrode material is deposited on the insulating material by a method selected from the group consisting of thick film printing, vapor deposition, screen deposition, spray coating, roller coating, vacuum deposition, thin film deposition, sputtering, evaporation, spin coating, and combinations thereof.

In an aspect of the second embodiment, the electrode material includes a working electrode, and wherein the electrode material is selected from the group consisting of glassy carbon, gold, platinum, palladium, nickel, silver, copper, lead, zinc, silver/carbon, and mixtures thereof.

In an aspect of the second embodiment, the electrode material includes a sheet.

In an aspect of the second embodiment, the electrode material includes a mesh.

In an aspect of the second embodiment, the electrode material includes a film.

In an aspect of the second embodiment, the electrode material includes a wire.

In an aspect of the second embodiment, the electrode material includes a first electrode material and a second electrode material, wherein the second electrode material includes a reference electrode material.

In an aspect of the second embodiment, the reference electrode material includes a sheet.

In an aspect of the second embodiment, the reference electrode material includes a mesh.

In an aspect of the second embodiment, the reference electrode material includes a film.

In an aspect of the second embodiment, the reference electrode material includes a wire.

In an aspect of the second embodiment, the insulating material includes a polymer in which oxygen is soluble.

In an aspect of the second embodiment, the insulating material includes a silicone or a hydrogel.

In an aspect of the second embodiment, the insulating material is selected from the group consisting of polyimide, polyester, polyurethane, perfluorinated polymer, polycarbonate, polyvinyl chloride, high-density polypropylene, low-density polypropylene, Parylene, epoxy, hydrogels, silicone, and mixtures thereof.

In an aspect of the second embodiment, the electrode material includes one or more wires, and wherein the composite stack is formed by molding or flattening the wires into the insulating material, thereby forming an integrated layer.

In an aspect of the second embodiment, the electrode material includes a first electrode material and a second electrode material, and wherein a thickness of the first electrode material is at least twice a thickness of the second electrode material.

In an aspect of the second embodiment, the insulating material includes a thickness of from about 1 micron to about 1000 microns.

In an aspect of the second embodiment, the insulating material includes a thickness of from about 1 micron to about 100 microns.

In an aspect of the second embodiment, the composite stack includes a first electrode material, a second electrode material, and a third electrode material; wherein the first electrode material includes a first working electrode, wherein the second electrode material includes a second working electrode, and wherein the third electrode material includes a reference electrode.

In an aspect of the second embodiment, the composite stack includes a first electrode material, and wherein the first electrode material includes a working electrode.

In an aspect of the second embodiment, the method further includes providing a reference electrode.

In an aspect of the second embodiment, the composite stack further includes a second electrode material, wherein the second electrode material includes a counter electrode.

In an aspect of the second embodiment, the method further includes providing a reference electrode.

In an aspect of the second embodiment, the composite stack further includes a third electrode material, wherein the third electrode material includes a reference electrode.

In an aspect of the second embodiment, the composite stack includes a first electrode material including a first working electrode, a second electrode material including a second working electrode, and a third electrode material including a counter electrode.

In an aspect of the second embodiment, the method further includes providing a reference electrode.

In an aspect of the second embodiment, the step of rolling the composite stack includes selectively rolling the electrode material and the insulating material on a rolling mandrel.

In an aspect of the second embodiment, the step of cutting away is selected from the group consisting of cutting away with a knife, cutting away with a water jet, cutting away with a laser, cutting away with a plasma arc, and cutting away with an oxyfuel.

In an aspect of the second embodiment, the composite stack includes an elastomeric material, and the method further includes: freezing the spiral roll, whereby the elastomeric material is hardened, wherein the step of freezing is conducted before the step of cutting away.

In an aspect of the second embodiment, the step of cutting away is selected from the group consisting of cutting away with a knife, cutting away with a water jet, cutting away with a laser, cutting away with a plasma arc, and cutting away with an oxyfuel.

In an aspect of the second embodiment, the step of cutting away a portion of the spiral roll includes cutting along a plane perpendicular to a longitudinal axis of the spiral roll.

In an aspect of the second embodiment, the step of cutting away a portion of the spiral roll includes cutting along a plane that is at an angle of less than 90 degrees to a longitudinal axis of the spiral roll.

In an aspect of the second embodiment, the step of cutting away a portion of the spiral roll includes cutting along a longitudinal axis of the spiral roll.

In an aspect of the second embodiment, the step of cutting away a portion of the spiral roll includes cutting fully across a diameter of the spiral roll.

In an aspect of the second embodiment, the step of cutting away a portion of the spiral roll includes cutting partially across a diameter of the spiral roll.

In an aspect of the second embodiment, the method further includes the step of post-processing the electrode array by subjecting at least one surface of the electrode array to machining, polishing, or shaping.

In an aspect of the second embodiment, the post-processing produces a non-planar surface on the electrode array.

In an aspect of the second embodiment, the method further includes the step of post-processing the electrode array by etching away a portion of the electrode material, whereby an etched away portion is obtained.

In an aspect of the second embodiment, the method further includes the step of filling the etched away portion with a polymer.

In a third embodiment, an electrode array manufactured according to the method of the second embodiment is provided.

In a fourth embodiment, a biosensor including an electrode array is manufactured according to the second embodiment.

In a fifth embodiment, a biosensor including the electrode array of the first embodiment is provided.

### BRIEF DESCRIPTION OF THE DRAWINGS

FIG. 1 is perspective view of a glucose sensor with an electrode system of one of the preferred embodiments.

FIG. 2 is a block diagram of the glucose sensor's electronics of one embodiment.

FIG. 3A is perspective view of a stack of materials used in the manufacture of the electrode system of one embodiment.

FIG. 3B is perspective view of a stack of materials used in the manufacture of the electrode system of an alternative embodiment.

FIG. 4 is a perspective view of the rolled material stack during the manufacture of the electrode system of one embodiment.

FIG. 5 is a perspective view of an electrode array that is formed by slicing along a plane perpendicular to the longitudinal axis of the spiral roll.

FIG. 6 is a perspective view of another electrode array that is formed by slicing along a plane that is at an angle other than 90 degrees to the longitudinal axis of the spiral roll.

FIG. 7 is a perspective view of another electrode array that is formed by slicing along the longitudinal axis of the spiral roll.

FIG. 8 is a top view of an electrode array of another alternative embodiment

FIG. 9 is a side view of another electrode array that is formed as depicted in FIG. 7 and shaped to form a curvature on a surface thereof.

FIG. 10 a side view of another electrode array that is formed as depicted in FIG. 7 and etched to form stepped down surfaces.

### DETAILED DESCRIPTION OF THE PREFERRED EMBODIMENT

The following description and examples illustrate a preferred embodiment of the present invention in detail. Those of skill in the art will recognize that there are numerous variations and modifications of this invention that are encompassed by its scope. Accordingly, the description of a preferred embodiment should not be deemed to limit the scope of the present invention.

Definitions

In order to facilitate an understanding of the preferred embodiments, a number of terms are defined below.

The term “analyte” as used herein is a broad term and is used in its ordinary sense, including, without limitation, to refer to a substance or chemical constituent in a biological fluid (for example, blood, interstitial fluid, cerebral spinal fluid, lymph fluid or urine) that can be analyzed. Analytes can include naturally occurring substances, artificial substances, metabolites, and/or reaction products. In some embodiments, the analyte for measurement by the sensing regions, devices, and methods is glucose. However, other analytes are contemplated as well, including but not limited to acarboxyprothrombin; acylcarnitine; adenine phosphoribosyl transferase; adenosine deaminase; albumin; alpha-fetoprotein; amino acid profiles (arginine (Krebs cycle), histidine/urocanic acid, homocysteine, phenylalanine/tyrosine, tryptophan); andrenostenedione; antipyrine; arabinitol enantiomers; arginase; benzoylecgonine (cocaine); biotinidase; biopterin; c-reactive protein; carnitine; carnosinase; CD4; ceruloplasmin; chenodeoxycholic acid; chloroquine; cholesterol; cholinesterase; conjugated 1-β hydroxy-cholic acid; cortisol; creatine kinase; creatine kinase MM isoenzyme; cyclosporin A; d-penicillamine; de-ethylchloroquine; dehydroepiandrosterone sulfate; DNA (acetylator polymorphism, alcohol dehydrogenase, alpha 1-antitrypsin, cystic fibrosis, Duchenne/Becker muscular dystrophy, glucose-6-phosphate dehydrogenase, hemoglobin A, hemoglobin S, hemoglobin C, hemoglobin D, hemoglobin E, hemoglobin F, D-Punjab, beta-thalassemia, hepatitis B virus, HCMV, HIV-1, HTLV-1, Leber hereditary optic neuropathy, MCAD, RNA, PKU, Plasmodium vivax, sexual differentiation, 21-deoxycortisol); desbutylhalofantrine; dihydropteridine reductase; diptheria/tetanus antitoxin; erythrocyte arginase; erythrocyte protoporphyrin; esterase D; fatty acids/acylglycines; free β-human chorionic gonadotropin; free erythrocyte porphyrin; free thyroxine (FT4); free tri-iodothyronine (FT3); fumarylacetoacetase; galactose/gal-1-phosphate; galactose-1-phosphate uridyltransferase; gentamicin; glucose-6-phosphate dehydrogenase; glutathione; glutathione perioxidase; glycocholic acid; glycosylated hemoglobin; halofantrine; hemoglobin variants; hexosaminidase A; human erythrocyte carbonic anhydrase I; 17-alpha-hydroxyprogesterone; hypoxanthine phosphoribosyl transferase; immunoreactive trypsin; lactate; lead; lipoproteins ((a), B/A-1, β); lysozyme; mefloquine; netilmicin; phenobarbitone; phenytoin; phytanic/pristanic acid; progesterone; prolactin; prolidase; purine nucleoside phosphorylase; quinine; reverse tri-iodothyronine (rT3); selenium; serum pancreatic lipase; sissomicin; somatomedin C; specific antibodies (adenovirus, anti-nuclear antibody, anti-zeta antibody, arbovirus, Aujeszky's disease virus, dengue virus, Dracunculus medinensis, Echinococcus granulosus, Entamoeba histolytica, enterovirus, Giardia duodenalisa, Helicobacter pylori, hepatitis B virus, herpes virus, HIV-1, IgE (atopic disease), influenza virus, Leishmania donovani, leptospira, measles/mumps/rubella, Mycobacterium leprae, Mycoplasma pneumoniae, Myoglobin, Onchocerca volvulus, parainfluenza virus, Plasmodium falciparum, poliovirus, Pseudomonas aeruginosa, respiratory syncytial virus, rickettsia (scrub typhus), Schistosoma mansoni, Toxoplasma gondii, Trepenoma pallidium, Trypanosoma cruzi/rangeli, vesicular stomatis virus, Wuchereria bancrofti, yellow fever virus); specific antigens (hepatitis B virus, HIV-1); succinylacetone; sulfadoxine; theophylline; thyrotropin (TSH); thyroxine (T4); thyroxine-binding globulin; trace elements; transferrin; UDP-galactose-4-epimerase; urea; uroporphyrinogen I synthase; vitamin A; white blood cells; and zinc protoporphyrin. Salts, sugar, protein, fat, vitamins and hormones naturally occurring in blood or interstitial fluids can also constitute analytes in certain embodiments. The analyte can be naturally present in the biological fluid, for example, a metabolic product, a hormone, an antigen, an antibody, and the like. Alternatively, the analyte can be introduced into the body, for example, a contrast agent for imaging, a radioisotope, a chemical agent, a fluorocarbon-based synthetic blood, or a drug or pharmaceutical composition, including but not limited to insulin; ethanol; cannabis (marijuana, tetrahydrocannabinol, hashish); inhalants (nitrous oxide, amyl nitrite, butyl nitrite, chlorohydrocarbons, hydrocarbons); cocaine (crack cocaine); stimulants (amphetamines, methamphetamines, Ritalin, Cylert, Preludin, Didrex, PreState, Voranil, Sandrex, Plegine); depressants (barbituates, methaqualone, tranquilizers such as Valium, Librium, Miltown, Serax, Equanil, Tranxene); hallucinogens (phencyclidine, lysergic acid, mescaline, peyote, psilocybin); narcotics (heroin, codeine, morphine, opium, meperidine, Percocet, Percodan, Tussionex, Fentanyl, Darvon, Talwin, Lomotil); designer drugs (analogs of fentanyl, meperidine, amphetamines, methamphetamines, and phencyclidine, for example, Ecstasy); anabolic steroids; and nicotine. The metabolic products of drugs and pharmaceutical compositions are also contemplated analytes. Analytes such as neurochemicals and other chemicals generated within the body can also be analyzed, such as, for example, ascorbic acid, uric acid, dopamine, noradrenaline, 3-methoxytyramine (3MT), 3,4-dihydroxyphenylacetic acid (DOPAC), homovanillic acid (HVA), 5-hydroxytryptamine (5HT), and 5-hydroxyindoleacetic acid (FHIAA).

The terms “operable connection,” “operably connected,” and “operably linked” as used herein are broad terms and are used in their ordinary sense, including, without limitation, one or more components being linked to another component(s) in a manner that allows transmission of signals between the components. For example, one or more electrodes can be used to detect the amount of analyte in a sample and convert that information into a signal; the signal can then be transmitted to a circuit. In this case, the electrode is “operably linked” to the electronic circuitry.

The term “host” as used herein is a broad term and is used in its ordinary sense, including, without limitation, mammals, particularly humans.

The terms “electrochemically reactive surface” and “electroactive surface” as used herein are broad terms and are used in their ordinary sense, including, without limitation, the surface of an electrode where an electrochemical reaction takes place. In one example, a working electrode measures hydrogen peroxide produced by the enzyme catalyzed reaction of the analyte being detected reacts creating an electric current (for example, detection of glucose analyte utilizing glucose oxidase produces H₂O₂ as a by product, H₂O₂ reacts with the surface of the working electrode producing two protons (2H⁺), two electrons (2e⁻) and one molecule of oxygen (O₂) which produces the electronic current being detected). In the case of the counter electrode, a reducible species, for example, O₂ is reduced at the electrode surface in order to balance the current being generated by the working electrode.

The term “sensing region” as used herein is a broad term and is used in its ordinary sense, including, without limitation, the region of a monitoring device responsible for the detection of a particular analyte. The sensing region generally comprises a non-conductive body, a working electrode (anode), a reference electrode (optional), and/or a counter electrode (cathode) passing through and secured within the body forming electrochemically reactive surfaces on the body and an electronic connective means at another location on the body, and a multi-domain membrane affixed to the body and covering the electrochemically reactive surface.

The term “electronic connection” as used herein is a broad term and is used in its ordinary sense, including, without limitation, any electronic connection known to those in the art that can be utilized to interface the sensing region electrodes with the electronic circuitry of a device such as mechanical (for example, pin and socket) or soldered.

The term “curvature,” “curved portion,” and “curved,” as used herein, are broad terms and is used in their ordinary sense, including, without limitation, one or more arcs defined by one or more radii.

Overview

Electrode arrays, methods for manufacturing electrode arrays, and the use of electrode arrays in electrochemical applications are disclosed. The electrode arrays of the preferred embodiments can be used in electrochemical applications performed with electrodes such as analyte detection, energy conversion, and the like. In some embodiments, the electrode array can be used in an amperometric, coulometric, conductimetric, and/or potentiometric analyte sensor. In some embodiments, the electrode array can be used with any of a variety of known in vitro or in vivo analyte sensors or monitors, such as are disclosed in U.S. Pat. No. 6,001,067 to Shults et al.; U.S. Pat. No. 6,702,857 to Brauker et al.; U.S. Pat. No. 6,212,416 to Ward et al.; U.S. Pat. No. 6,119,028 to Schulman et al.; U.S. Pat. No. 6,400,974 to Lesho; U.S. Pat. No. 6,595,919 to Bemer et al.; U.S. Pat. No. 6,141,573 to Kurnik et al.; U.S. Pat. No. 6,122,536 to Sun et al.; European Patent Application EP 1153571 to Varall et al.; U.S. Pat. No. 6,512,939 to Colvin et al.; U.S. Pat. No. 5,605,152 to Slate et al.; U.S. Pat. No. 4,431,004 to Bessman et al.; U.S. Pat. No. 4,703,756 to Gough et al.; U.S. Pat. No. 6,514,718 to Heller et al.; U.S. Pat. No. 5,985,129 to Gough et al.; WO Patent Application Publication No. 04/021877 to Caduff; U.S. Pat. No. 5,494,562 to Maley et al.; U.S. Pat. No. 6,120,676 to Heller et al.; and U.S. Pat. No. 6,542,765 to Guy et al., each of which is hereby incorporated by reference in its entirety. In alternative embodiments, the electrode arrays of the preferred embodiments can be used for other applications, for example, fuel cells and batteries.

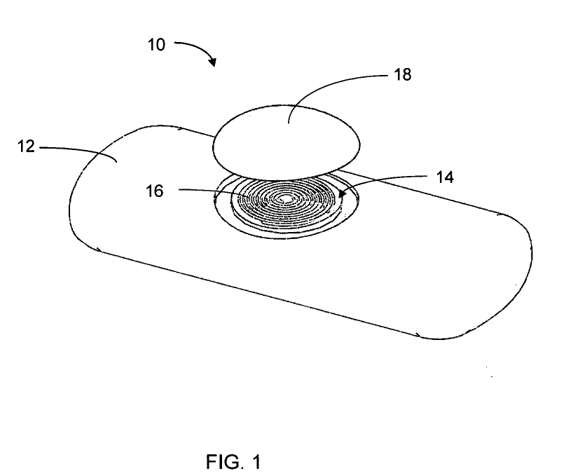

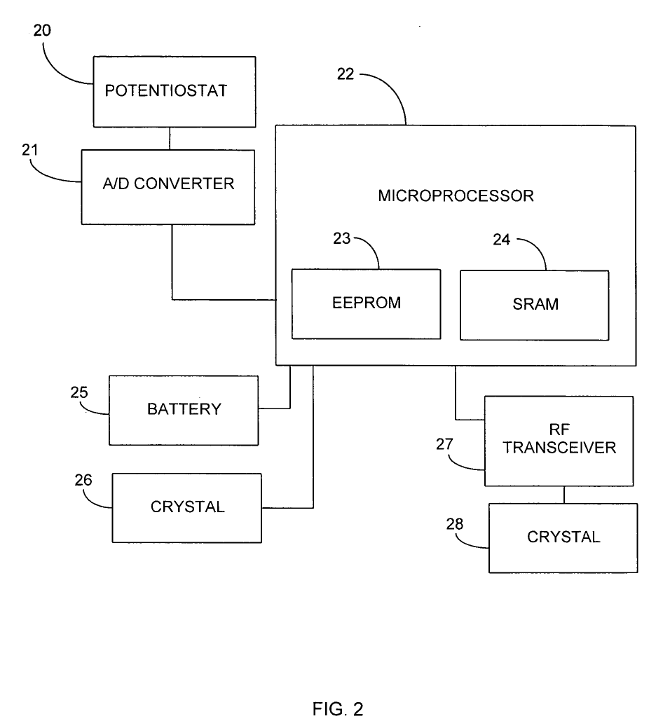

FIG. 1 is an exploded perspective view of one exemplary embodiment comprising an implantable glucose sensor 10 that utilizes amperometric electrochemical sensor technology to measure glucose. In this exemplary embodiment, a body 12 with a sensing region 14 houses the electrode array 16 and sensor electronics, which are described in more detail with reference to FIG. 2.

In this embodiment, the electrode array is operably connected to the sensor electronics (FIG. 2) and includes electroactive surfaces, which are covered by a membrane system 18. The membrane system 18 is disposed over the electroactive surfaces of the electrode array 16 and provides one or more of the following functions: 1) protection of the exposed electrode surface from the biological environment; 2) diffusion resistance (limitation) of the analyte; 3) a catalyst for enabling an enzymatic reaction; 4) limitation or blocking of interfering species; and 5) hydrophilicity at the electrochemically reactive surfaces of the sensor interface, for example, such as described in co-pending U.S. patent application Ser. No. 10/838,912, filed May 3, 2004 and entitled “IMPLANTABLE ANALYTE SENSOR,” which is incorporated herein by reference in its entirety. The membrane system can be attached to the sensor body 12 by mechanical or chemical methods such as are described in co-pending U.S. patent application Ser. No. 10/885,476 filed Jul. 6, 2004 and entitled “SYSTEMS AND METHODS FOR MANUFACTURE OF AN ANALYTE-MEASURING DEVICE INCLUDING A MEMBRANE SYSTEM” and U.S. patent application Ser. No. 10/838,912 filed May 3, 2004 and entitled, “IMPLANTABLE ANALYTE SENSOR”, which are incorporated herein by reference in their entireties.

In some embodiments, the electrode array, which is located on or within the sensing region 14, is comprised of at least a working electrode and a reference electrode with an insulating material disposed therebetween. In some alternative embodiments, additional electrodes can be included within the electrode array, for example, a three-electrode system (working, reference, and counter electrodes) and/or an additional working electrode (which can be used to generate oxygen, measure an additional analyte, or can be configured as a baseline subtracting electrode, for example). Other electrode array configurations are described in more detail elsewhere herein.

In the alternative embodiment wherein the electrode array includes a three-electrode system (working, counter, and reference electrodes), the counter electrode is provided to balance the current generated by the species being measured at the working electrode. In a glucose oxidase-based glucose sensor, the species measured at the working electrode is H₂O₂. Glucose oxidase catalyzes the conversion of oxygen and glucose to hydrogen peroxide and gluconate according to the following reaction:
Glucose+O₂→Gluconate+H₂O₂

The change in H₂O₂ can be monitored to determine glucose concentration, because for each glucose molecule metabolized, there is a proportional change in the product H₂O₂. Oxidation of H₂O₂ by the working electrode is balanced by reduction of ambient oxygen, enzyme generated H₂O₂, or other reducible species at the counter electrode. The H₂O₂ produced from the glucose oxidase reaction further reacts at the surface of working electrode and produces two protons (2H+), two electrons (2e−), and one oxygen molecule (O2). In such embodiments, because the counter electrode utilizes oxygen as an electron acceptor, the most likely reducible species for this system is oxygen or enzyme generated peroxide. There are two main pathways by which oxygen can be consumed at the counter electrode. These pathways include a four-electron pathway to produce hydroxide and a two-electron pathway to produce hydrogen peroxide. In addition to the counter electrode, oxygen is further consumed by the glucose oxidase within the enzyme layer. Therefore, due to the oxygen consumption by both the enzyme and the counter electrode, there is a net consumption of oxygen within the electrode system. Theoretically, in the domain of the working electrode there is significantly less net loss of oxygen than in the region of the counter electrode. In addition, there is a close correlation between the ability of the counter electrode to maintain current balance and sensor function. Taken together, it is believed that counter electrode function becomes limited before the enzyme reaction becomes limited when oxygen concentration is lowered.

Subcutaneously implanted sensors undergo transient ischemia that can compromise sensor function. For example, because of the enzymatic reaction required for an implantable amperometric glucose sensor, oxygen must be in excess over glucose in order for a sensor to effectively function as a glucose sensor. If glucose is in excess, the sensor becomes an oxygen sensitive device. This can happen during periods of transient ischemia that occur, for example, under certain postures or when the region around the implanted sensor is compressed so that blood is forced out of the capillaries. Such ischemic periods observed in implanted sensors can last for a few seconds or even an hour or longer.

Consequently, certain limitations of conventional enzymatic glucose sensors, such as are described above, are caused by oxygen deficiencies. For example, if oxygen is deficient relative to the amount of glucose, then the enzymatic reaction is limited by oxygen rather than glucose. Thus, the output signal is indicative of the oxygen concentration rather than the glucose concentration, producing erroneous signals.

In one embodiment, the electrochemical measuring circuit can be a potentiostat. The potentiostat applies a constant potential to the working and reference electrodes to determine a current value. The current that is produced at the working electrode is proportional to the diffusional flux of H₂O₂. Accordingly, a raw signal can be produced that is representative of the concentration of glucose in the user's body, and therefore can be utilized to estimate a meaningful glucose value, such as described elsewhere herein.

FIG. 2 is a block diagram that illustrates one possible configuration of the sensor electronics in one embodiment. In this embodiment, a potentiostat 20 is shown, which is operatively connected to electrode array 16 (FIG. 1) to obtain a current value, and includes a resistor (not shown) that translates the current into voltage. The A/D converter 21 digitizes the analog signal into “counts” for processing. Accordingly, the resulting raw data signal in counts is directly related to the current measured by the potentiostat.

A microprocessor 22 is the central control unit that houses EEPROM 23 and SRAM 24, and controls the processing of the sensor electronics. The alternative embodiments can utilize a computer system other than a microprocessor to process data, as described herein. In some alternative embodiments, an application-specific integrated circuit (ASIC) can be used for some or all the sensor's central processing. EEPROM 23 provides semi-permanent storage of data, storing data such as sensor ID and programming to process data signals (for example, programming for data smoothing such as described elsewhere herein). SRAM 24 is used for the system's cache memory, for example for temporarily storing recent sensor data.

The battery 25 is operatively connected to the microprocessor 22 and provides the power for the sensor. In one embodiment, the battery is a Lithium Manganese Dioxide battery, however any appropriately sized and powered battery can be used. In some embodiments, a plurality of batteries can be used to power the system. Quartz Crystal 26 is operatively connected to the microprocessor 22 and maintains system time for the computer system.

The RF Transceiver 27 is operably connected to the microprocessor 22 and transmits the sensor data from the sensor to a receiver. Although a RF transceiver is shown here, some other embodiments can include a wired rather than wireless connection to the receiver. In other embodiments, the sensor can be transcutaneously connected via an inductive coupling, for example. The quartz crystal 28 provides the system time for synchronizing the data transmissions from the RF transceiver. The transceiver 27 can be substituted with a transmitter in one embodiment.

Although FIGS. 1 and 2 and associated text illustrate and describe one exemplary embodiment of an implantable glucose sensor, the electrode array, electronics and method of manufacture of the preferred embodiments described below can be implemented on any known electrochemical sensor, including those described in co-pending U.S. patent application Ser. No. 10/838,912 filed May 3, 2004 and entitled, “IMPLANTABLE ANALYTE SENSOR”; U.S. patent application Ser. No. 10/789,359 filed Feb. 26, 2004 and entitled, “INTEGRATED DELIVERY DEVICE FOR A CONTINUOUS GLUCOSE SENSOR”; “OPTIMIZED SENSOR GEOMETRY FOR AN IMPLANTABLE GLUCOSE SENSOR”; and U.S. Application No. 10/633,367 filed Aug. 1, 2003 entitled, “SYSTEM AND METHODS FOR PROCESSING ANALYTE SENSOR DATA”, all of which are incorporated herein by reference in their entireties.

Manufacture of Electrode Array

Methods for manufacturing electrode arrays suitable for electrochemical applications using bulk materials and/or efficient processes are provided herein. The methods include rolling a composite stack of electrode and insulating materials, after which the roll can be cut in a variety of cross-sections to form a variety of electrode array configurations, shapes, and thicknesses.

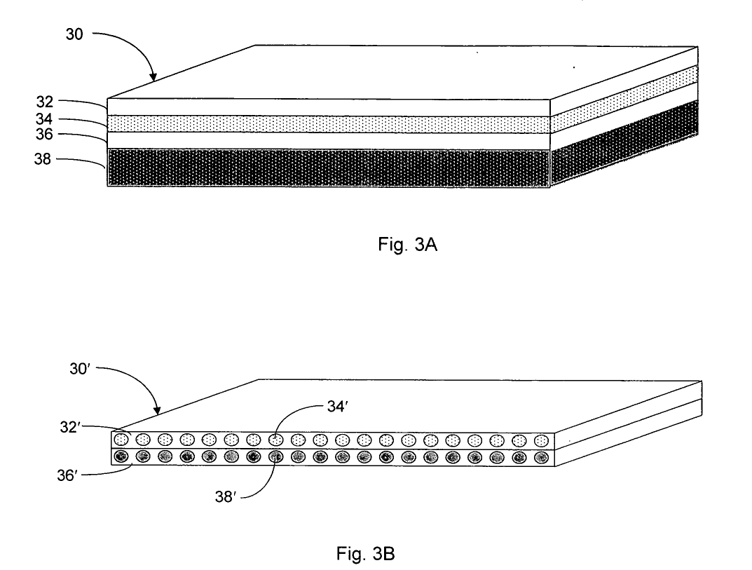

FIG. 3A is perspective view of a stack of materials used in the manufacture of an electrode system of one embodiment. In this embodiment, the composite stack 30 comprises a first insulating layer 32, a first electrode layer 34, a second insulating layer 36, and a second electrode layer 38. FIG. 3A shows continuous layers (for example, as compared to FIG. 3B)

In some embodiments, the composite stack can include only one working electrode layer. Alternatively, the composite stack can include one working and one counter electrode layer, or one working and one reference electrode layer, or multiple working electrode layers with one counter electrode layer, or any combination of one or more working electrode layers, counter electrode layers, and/or reference electrode layers.

Insulating material can be layered between the electrode layers. In some embodiments, the insulating material can be a thin layer such that the electrodes are in relatively close proximity (for example, spaced apart by from about 1 micron or less to about 1000 microns or more). In one embodiment, the insulating material comprises a layer having a thickness of from about 1 micron or less to about 100, 200, 300, 400, 500, 600, 700, 800, or 900 microns or more. Preferably, the insulating material comprises a layer thickness of from about 5, 10 15, 20, 25, 30, 35, 40, or 45 microns to about 55, 60, 65, 70, 75, 80, 85, 90, or 95 microns, and most preferably about 50 microns.

In some embodiments, an insulating material is selected that has a high oxygen solubility or permeability (for example, silicone, hydrogel, fluorocarbon, perfluorocarbon, or the like), which aids in transporting oxygen between the electrodes and/or through the electrode array (for example, from the bottom to the top or vice versa). Utilization of a high oxygen soluble material is advantageous because it is believed to dynamically retain high oxygen availability to oxygen-utilizing sources (for example, an enzyme and/or a counter electrode of an electrochemical cell).

The phrases “high oxygen solubility” and “high oxygen soluble” as used herein are broad phrases and are used in their ordinary sense, including, without limitation, a domain or material property that includes higher oxygen solubility than aqueous media so that it concentrates oxygen from the. biological fluid surrounding the membrane system. In some preferred embodiments, a high oxygen solubility polymer has at least about 3× higher oxygen solubility than aqueous media, more preferably at least about 4×, 5×, or 6× higher oxygen solubility than aqueous media, and most preferably at least about 7×, 8×, 9×, 10× or more higher oxygen solubility than aqueous media. In one embodiment, high oxygen solubility is defined as having higher oxygen solubility than at least one of a hydrocarbonaceous polymer and an oxyhydrocarbon polymer (a hydrocarbonaceous polymer is a polymeric material consisting of carbon and hydrogen atoms and an oxyhydrocarbonaceous polymer is a polymeric material consisting of carbon, hydrogen, and oxygen atoms). Oxygen solubility can be measured using any known technique, for example by removing the oxygen from the polymer (namely, solution) via at least three Freeze-Pump-Thaw cycles and then measuring the resultant oxygen (for example, using a manometer).

Oxygen permeability (Dk) is calculated as diffusion multiplied by solubility. Oxygen Permeability is conveniently reported in units of Barrers (1 Barrer=10⁻¹⁰ cm³ O₂ (STP) cm/cm²s cMHg). Insulating materials of preferred embodiments that have a high oxygen permeability typically have an oxygen permeability of from about 1 Barrer or less to about 1000 Barrers or more, preferably from about 1, 2, 3, 4, 5, 6, 7, 8, 9, 10, 15, 20, 25, 30, 35, 40, 45, 50, 55, 60, 65, 70, 75, 80, 85, 90, 95, or 100 Barrers to about 125, 150, 175, 200, 225, 250, 275, 300, 325, 350, 375, 400, 425, 450, 475, 500, 550, 600, 650, 700, 750, 800, 850, 900, or 950 Barrers.

In one exemplary embodiment, the properties of silicone (and/or silicone compositions) inherently enable insulating materials formed from silicone to act as a high oxygen solubility domain. The characteristics of a high oxygen soluble domain enhance function in an electrochemical sensor by applying a higher availability of oxygen to certain locations, for example oxygen-utilizing sources.

In some embodiments, the insulating material can comprise one or more different materials (for example, one material that provides structural support (for example, epoxy) and another material that provides enhanced oxygen availability (for example, silicone)) that can be blended, layered, or otherwise combined. Any suitable insulating material can be employed as a layer or layers between the electrode layers.

A variety of electrode and insulating materials can be. used. The working and counter electrode layers can comprise any suitable metal or conductive polymer electrode material, such as glassy carbon, gold, platinum, palladium, nickel, silver, copper, lead, zinc, or silver/carbon, for example. The reference electrode can comprise any suitable material, such as Silver/Silver Chloride or calomel, for example. The insulating layers can comprise polyimide, polyester, polyurethane, perfluorinated polymer, polycarbonate, polyvinyl chloride, high-density polypropylene, low-density polypropylene, Parylene, epoxy, hydrogels, or silicone, for example.

In some embodiments, the counter electrode layer has a thickness of at least about twice the thickness of the working electrode layer (see FIG. 3A). In one embodiment, the counter electrode layer has a thickness of at least about three, four, five, or six times the thickness of the working electrode layer. However, in certain embodiments the counter electrode can have a thickness of less than about twice the thickness of the working electrode layer.

In the embodiments wherein the counter electrode layer has a thickness of at least about two times the thickness of the working electrode layer, the counter electrode has a surface area at least about twice the surface area of the working electrode, when the electrode array is manufactured as described herein. An increased surface area in the counter electrode relative to the working electrode can be useful in substantially increasing the electrode's ability to utilize oxygen as a substrate, such as is described in co-pending U.S. patent application Ser. No. 09/916,711 filed Jul. 27, 2001 and entitled “SENSOR HEAD FOR USE WITH IMPLANTABLE DEVICE,” which is incorporated herein by reference in its entirety.

In some embodiments, the electrode layers can be spaced in relatively close proximity to each other (for example, from about 1 micron or less to about 1000 microns or more). Close proximity of the electrodes creates shared local environments such that the oxygen generated at the counter electrode(s) can be easily shared with and used by the working electrode(s), for example. This configuration creates an electrode array that optimizes availability of oxygen to key areas of the electrode array. However, the layers can be of any suitable thickness, as appreciated by one skilled in the art, in order to create a desired electrode configuration.

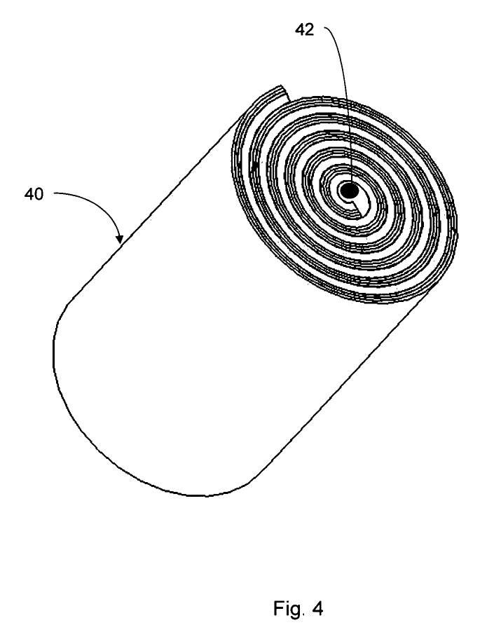

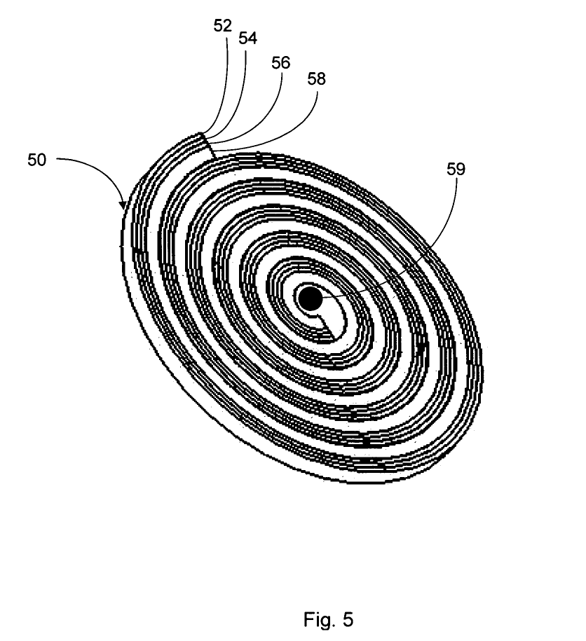

In one embodiment, sheets of electrode and insulating material are layered to form the composite; the layers can be adhered by any known technique. In one embodiment, the materials can be layered, but not adhered. In another embodiment, one or more of the electrode and/or insulating layers can be deposited using known techniques such as thick film printing, vapor deposition, screen deposition, spray coating, roller coating, vacuum deposition, thin film deposition, sputtering, evaporation, spin coating, and the like. In another embodiment, the electrode layers can comprise a mesh. In another embodiment, the one or more electrode layers can comprise wires, wherein the wires are flattened and/or molded into or onto the insulating material to form integrated layers (see FIG. 4B). In alternative embodiments, any combination of the above layering techniques can be used in conjunction with one or more layers.

FIG. 3B is perspective view of a stack of materials used in the manufacture of the electrode system of an alternative embodiment. In this embodiment, the composite stack 30′ comprises a first integrated layer including a first set of wire electrodes 34′, for example using working electrode materials, embedded in an insulating material 32′ and a second integrated layer, including a second set of wire electrodes 36′, for example, using reference or counter electrode materials, embedded in an insulating material 38′. Although two integrated layers are illustrated, one, two, three, or more integrated layers can be included in the stack, for example, one or more working, counter, and/or reference electrode wire sets embedded in insulating layers. Additionally, one or more integrated layers (as shown in FIG. 3B) can be combined with one or more continuous layers (as shown in FIG. 3A) to form a composite stack, for example, one integrated working electrode layer combined with a continuous counter and/or reference electrode layer surrounded by insulating materials.

FIG. 4 is a perspective view of a composite stack that has been rolled to form a spiral roll 40. The composite can be rolled in any suitable manner, such as methods used by battery manufacturers, for example. In one alternative embodiment, individual layers can be formed during the rolling process by intermittently controlled thin-film vapor deposition of the electrode and insulating materials on an actively rolling mandrel.

In one embodiment, a central reference electrode 42 can optionally be incorporated into the center of the rolled composite stack in place of, or in combination with, a reference electrode layer. The central reference electrode 42 can be placed therein before or after the rolling process. The central positioning of the reference electrode relative to the other electrodes can be advantageous to minimize IR drop (wherein IR is the current (i) multiplied by the solution resistance (R)), to maintain symmetrical field lines, and for ease of manufacture.

The overall nature of this layering and rolling method is advantageous for its relatively low cost and simplicity of manufacture. Additionally, the embodiments described herein that use bulk materials, particularly for the electrode layers (for example, platinum sheet metal, wire, and mesh) comprise compositions of a greater purity than layers formed using film techniques such as deposition, spraying, and the like, thereby avoiding electrode contamination. However, film techniques can be suitable for use in some embodiments. The methods provided herein allow for a variety of electrode configurations using pure-non-contaminated bulk materials. Furthermore, the utilization of bulk material to form electrodes as disclosed herein is generally not susceptible to delamination.

Electrode Array Configuration

After the composite is rolled into. a spiral, the spiral can by cut, sliced, and/or dissected in numerous ways to form the electrode array. The spiral roll 40 can be sliced using any known cutting technique, for example, cutting with a knife or blade, water jet cutting, laser cutting, plasma arc cutting, or oxyfuel cutting. Freezing (for example, cryogenic techniques) can be used to facilitate the cutting of elastomeric materials (for example, silicone). FIGS. 5 through 8 are perspective views of exemplary sliced sections of the spiral. The section angle and thickness can be altered as desired for particular effects, each of which is encompassed within the preferred embodiments. Additionally, the overall dimensions of the electrode array can be controlled during slicing of the spiral roll 40 (for example, partial vs. complete sectioning or thick vs. thin slicing) and/or can be controlled by the overall dimensions of the composite stack 30 that forms the spiral roll 40.

FIG. 5 is a perspective view of an electrode array 50 formed by slicing along a plane perpendicular to the longitudinal axis of the spiral roll of FIG. 4. The thickness of the electrode array can be sliced to any desired dimension, for example, from about 1 micron or less to about 1 cm, or more, preferably from about 5, 10, 15, 20, 25, 30, 35, 40, 45, 50, 55, 60, 65, 70, 76, 80, 85, 90, or 100 microns to about 1, 1.5, 2.0, 2.5, 3.0, 3.5, 4.0, 4.5, 5.0, 5.5, 6.0, 6.5, 7.0, 7.5, 8.0, 8.5, 9.0, or 9.5 mm, and more preferably from about 150, 200, 250, 300, 350, 400, or 450 microns to about 500, 550, 600, 650, 700, 750, 800, 850, 900, or 950 microns. However, any suitable thickness can be employed.

In the embodiment illustrated in FIG. 5, the electrode array includes a first insulating layer 52, a working electrode layer 54, a second insulating layer 56, a counter electrode layer 58, and a central reference electrode 59. The composition and configuration of the electrode array 50, however, can depend on the chosen composition and configuration of materials that formed the composite stack and/or spiral roll 40, such as described in more detail with reference to FIGS. 3 and 4.

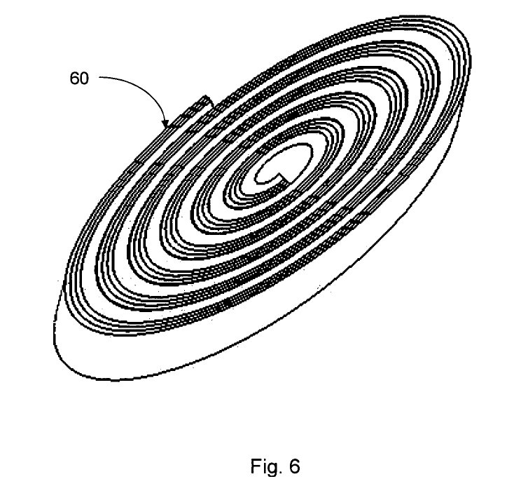

FIG. 6 is a perspective view of an alternative embodiment, wherein the electrode array 60 was formed by slicing the spiral roll 40 along a plane that is at an angle other than 90 degrees to the longitudinal axis. In this exemplary embodiment, the angle is cut at 45 degrees to the longitudinal axis, however any suitable angle of from about 90 to about 0 degrees can be employed, for example, an angle of from about 5, 10, 15, 20, 25, 30, 35, or 40 degrees to about 50, 55, 60, 65, 70, 75, 80, or 85 degrees. An angled cut can provide increased surface area electrodes, which can offer benefits such as: 1) increasing the electrode array's ability to utilize oxygen as a substrate; 2) increasing the signal strength; and 3) increasing the distribution of the electrodes across the entire electrode array, thereby increasing the likelihood of efficient analyte transport, for example, around formations of barrier cells in an implantable device. See, e.g., U.S. Pat. No. 6,702,857 entitled “MEMBRANE FOR USE WITH IMPLANTABLE DEVICES,” the contents of which are hereby incorporated by reference in their entirety.

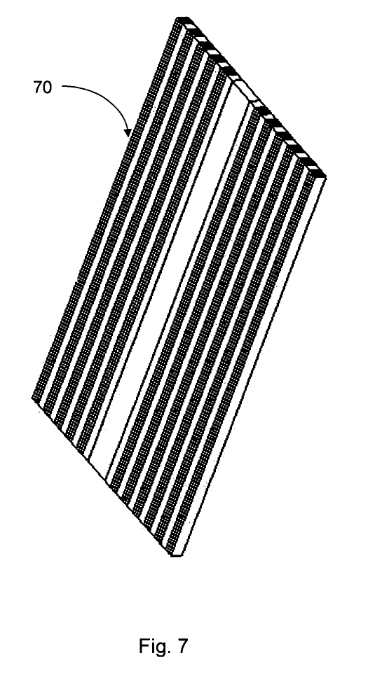

FIG. 7 is a perspective view of yet another alternative embodiment, wherein the electrode array 70 is formed by slicing along the longitudinal axis of the spiral roll 40.

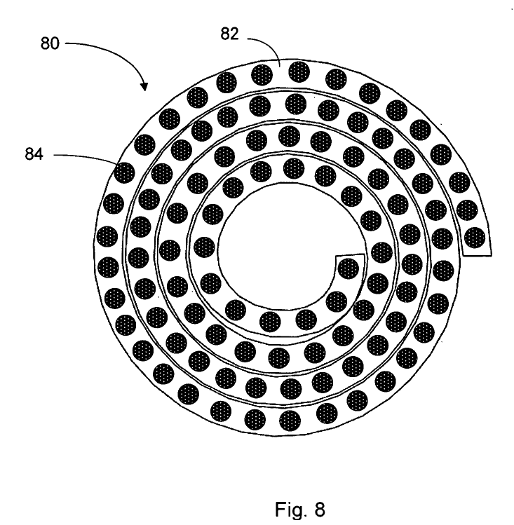

FIG. 8 is a top view of an electrode array in yet another alternative embodiment, wherein the electrode array 80 was formed by rolling an integrated electrode-insulating layer similar to the embodiment of FIG. 3B, but including only a single integrated layer formed from an insulating material 82 and set of wires 84 (for example, formed from material suitable for working electrodes). The rolled integrated layer is sliced perpendicular to the longitudinal axis of the spiral roll to form the section shown in FIG. 8. This embodiment can be advantageous in electrochemical devices that utilize cyclic voltammetry or other multi-potential applications. For example, wherein the spacing of the electrodes 84 allows a signal strength substantially equivalent to a continuous electrode layer (FIGS. 3A and FIGS. 5 to 7) due to the optimized diffusion of the electrodes 84, but provides a reduced capacitance of the electrodes 84 as compared to an equivalent continuous electrode layer.

The sections (described with reference to FIGS. 5 to 8) can be full sections, namely, taken entirely across the spiral roll. Alternatively, the sections can be partial cross-sections, that is, across only a part of the spiral roll, for example, through from about 5, 10, 15, 20, 25, 30, 35, 40, or 45% of the thickness of the roll to about 50, 55, 60, 65, 70, 75, 80, 85, 90, or 95% of the thickness of the roll.

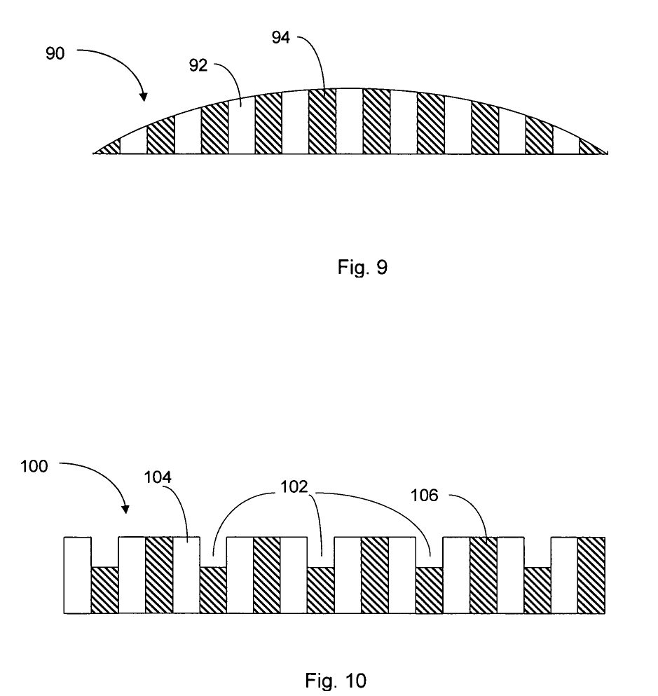

FIG. 9 is a side cross-sectional view of an electrode array in yet another alternative embodiment, wherein the electrode array 90 is machined, polished, or otherwise shaped to create a curvature on at least one surface. This shaping can be useful, for example, when an electrode array conforms to certain design requirements of an electrochemical device (for example, a device including a curvature). FIG. 9 shows the spacing of the insulating material 92 between the electrodes 94.

FIG. 10 is a side cross-sectional view of an electrode array in yet another alternative embodiment, wherein the electrode array 100 includes post-processing. In this embodiment, selected areas 102 are selectively etched away to form a stepped configuration and can left open or covered with a polymer. FIG. 10 shows the spacing of the insulating material 104 between the electrodes 106, wherein the electrodes are stepped down by etching. In certain alternative embodiments, the stepped areas can be formed within the composite stack prior to the rolling process. In some alternative embodiments, the selected areas 102 can be covered with certain materials. For example, in a combined oxygen and glucose sensor, the selected areas 102 can comprise oxygen-sensing electrodes and can be filled with silicone in order to block hydrogen peroxide but allow the transport of oxygen therethrough. In some alternative embodiments, the membrane system can be deposited directly into the selected areas 102, instead of or in addition to applying a membrane system such as is described in more detail with reference to FIG. 1.

In alternative embodiments, the electrode arrays of the preferred embodiments can be fabricated with non-planar surfaces. That is, the electrode array can be cut or machined from the spiral roll to conform to many non-planar surface device configurations. Additionally, electrode and insulating materials can be chosen with flexibility such that the electrode array can be shaped, wrapped, or formed around non-planar surfaces, for example, around cylindrical structures and/or needle-shaped sensors.

In yet another alternative electrode configuration, the electrode array can be cut or machined without rolling the composite stack, and that portion of the composite stack can be used as the electrode array.

The electrode arrays manufactured according to the methods of the preferred embodiments have numerous functional advantages over prior art electrodes, in addition to the manufacturing advantages described above. Firstly, in embodiments wherein the insulating material comprises an oxygen conducting material (for example, silicone or hydrogel), all electrode surfaces that are exposed to conductive liquid are also closely associated with the oxygen-conducting member. In these embodiments, the oxygen-conducting member can be continuous with a source of oxygen, either from the surrounding tissue, from an oxygen-producing electrode, or from an oxygen source (for example, oxygen storing containers near the electrode array). Accordingly, increased oxygen can be provided to the working electrode, and possibly to the enzyme layer above the electrode array.

An electrode array comprising working and counter electrodes in close proximity can optimize availability of oxygen produced by oxidation of hydrogen peroxide at the working electrode to the nearby counter electrode, such as is described in more detail elsewhere herein. Another advantage of placing the working and counter electrode in close proximity to each other is that the pH gradients generated at the electrodes can be neutralized. The working electrode produces H+as a byproduct of hydrogen peroxide oxidation while the counter electrode produces OH− as a byproduct of oxygen reduction. If the electrodes are separated, the pH of the local environment can change, causing shifts in the optimal bias potentials and damage to the membrane, biointerface, and/or cells. By placing the electrodes close enough so that the ions at one electrode can diffuse to the other electrode, the local pH environment remains neutral, eliminating any negative effects of pH imbalance.

As another noted advantage, in an implementation wherein the electrode array is used in an electrochemical sensor, the surface area of electrodes is directly related to signal strength due to the amount of surface area available for electrochemical reactions. Because the surface area can easily be controlled and/or increased by the thickness of the working electrode layer(s), the signal strength can also be controlled (and, for example, increased) accordingly.

The preferred embodiments are advantageous in an implantable biosensor (for example, a glucose sensor) for a variety of reasons. Most implanted devices provoke a local inflammatory response, called the foreign body response (FBR), which has long been recognized as limiting the function of implanted devices that require solute transport. The FBR has been well described in the literature. The innermost layer of the FBR is composed generally of macrophages and foreign body giant cells (herein referred to as the barrier cell layer). These cells form a monolayer of closely opposed cells over at least part of the surface of the device's membrane, which can function to block the transport of glucose (i.e., through the barrier cell layer). Therefore, by increasing the distribution of the electrodes across the entire electrode array, the likelihood of glucose transport around any barrier cell layer formation can be increased.

Methods and devices that are suitable for use in conjunction with aspects of the preferred embodiments are disclosed in co-pending U.S. patent application Ser. No. 10/885,476 filed Jul. 6, 2004 and entitled “SYSTEMS AND METHODS FOR MANUFACTURE OF AN ANALYTE-MEASURING DEVICE INCLUDING A MEMBRANE SYSTEM”; U.S. patent application Ser. No. 10/842,716, filed May 10, 2004 and entitled, “BIOINTERFACE MEMBRANES INCORPORATING BIOACTIVE AGENTS”; co-pending U.S. patent application Ser. No. 10/838,912 filed May 3, 2004 and entitled, “IMPLANTABLE ANALYTE SENSOR”; U.S. patent application Ser. No. 10/789,359 filed Feb. 26, 2004 and entitled, “INTEGRATED DELIVERY DEVICE FOR A CONTINUOUS GLUCOSE SENSOR”; U.S. Application No. 10/685,636 filed Oct. 28, 2003 and entitled, “SILICONE COMPOSITION FOR BIOCOMPATIBLE MEMBRANE”; U.S. Application No. 10/648,849 filed Aug. 22, 2003 and entitled, “SYSTEMS AND METHODS FOR REPLACING SIGNAL ARTIFACTS IN A GLUCOSE SENSOR DATA STREAM”; U.S. Application No. 10/646,333 filed Aug. 22, 2003 entitled, “OPTIMIZED SENSOR GEOMETRY FOR AN IMPLANTABLE GLUCOSE SENSOR”; U.S. Application No. 10/647,065 filed Aug. 22, 2003 entitled, “POROUS MEMBRANES FOR USE WITH IMPLANTABLE DEVICES”; U.S. Application No. 10/633,367 filed Aug. 1, 2003 entitled, “SYSTEM AND METHODS FOR PROCESSING ANALYTE SENSOR DATA”; U.S. Pat. No. 6,702,857 entitled “MEMBRANE FOR USE WITH IMPLANTABLE DEVICES”; U.S. Appl. No. 09/916,711 filed Jul. 27, 2001 and entitled “SENSOR HEAD FOR USE WITH IMPLANTABLE DEVICE”; U.S. Appl. No. 09/447,227 filed Nov. 22, 1999 and entitled “DEVICE AND METHOD FOR DETERMINING ANALYTE LEVELS”; U.S. Appl. No. 10/153,356 filed May 22, 2002 and entitled “TECHNIQUES TO IMPROVE POLYURETHANE MEMBRANES FOR IMPLANTABLE GLUCOSE SENSORS”; U.S. Pat. No. 6,741,877 entitled “DEVICE AND METHOD FOR DETERMINING ANALYTE LEVELS”; U.S. Pat. No. 6,558,321 filed Aug. 11, 2000 and entitled “SYSTEMS AND METHODS FOR REMOTE MONITORING AND MODULATION OF MEDICAL DEVICES”; and U.S. Appl. No. 09/916,858 filed Jul. 27, 2001 and entitled “DEVICE AND METHOD FOR DETERMINING ANALYTE LEVELS,” as well as issued patents including U.S. Pat. No. 6,001,067 issued Dec. 14, 1999 and entitled “DEVICE AND METHOD FOR DETERMINING ANALYTE LEVELS”; U.S. Pat. No. 4,994,167 issued Feb. 19, 1991 and entitled “BIOLOGICAL FLUID MEASURING DEVICE”; U.S. Pat. No. 4,757,022 filed Jul. 12, 1988 and entitled “BIOLOGICAL FLUID MEASURING DEVICE”; U.S. Appl. No. 60/490,010 filed Jul. 25, 2003 and entitled “INCREASING BIAS FOR OXYGEN PRODUCTION IN AN ELECTRODE ASSEMBLY”; U.S. Appl. No. 60/490,009 filed Jul. 25, 2003 and entitled “OXYGEN ENHANCING ENZYME MEMBRANE FOR ELECTROCHEMICAL SENSORS”; U.S. Appl. No. 60/490,208 filed Jul. 25, 2003 and entitled “ELECTRODE ASSEMBLY WITH INCREASED OXYGEN GENERATION”; U.S. Appl. No. 60/490,007 filed Jul. 25, 2003 and entitled “OXYGEN-GENERATING ELECTRODE FOR USE IN ELECTROCHEMICAL SENSORS”; U.S. Appl. No. __/___,___ filed on even date herewith and entitled “INCREASING BIAS FOR OXYGEN PRODUCTION IN AN ELECTRODE ASSEMBLY”; U.S. Appl. No. __/___,___ filed on even date herewith and entitled “OXYGEN ENHANCING ENZYME MEMBRANE FOR ELECTROCHEMICAL SENSORS”; U.S. Appl. No. __/___,___ filed on even date herewith and entitled “ELECTRODE ASSEMBLY WITH INCREASED OXYGEN GENERATION”; U.S. Appl. No. __/___,___ filed on even date herewith and entitled “ELECTRODE SYSTEMS FOR ELECTROCHEMICAL SENSORS”. The foregoing patent applications and patents are incorporated herein by reference in their entireties.

All references cited herein are incorporated herein by reference in their entireties. To the extent publications and patents or patent applications incorporated by reference contradict the disclosure contained in the specification, the specification is intended to supersede and/or take precedence over any such contradictory material.

The term “comprising” as used herein is synonymous with “including,” “containing,” or “characterized by,” and is inclusive or open-ended and does not exclude additional, unrecited elements or method steps.

All numbers expressing quantities of ingredients, reaction conditions, and so forth used in the specification and claims are to be understood as being modified in all instances by the term “about.” Accordingly, unless indicated to the contrary, the numerical parameters set forth in the specification and attached claims are approximations that can vary depending upon the desired properties sought to be obtained by the present invention. At the very least, and not as an attempt to limit the application of the doctrine of equivalents to the scope of the claims, each numerical parameter should be construed in light of the number of significant digits and ordinary rounding approaches.

The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention as embodied in the attached claims.

1. An electrode array for use in an electrochemical device, the electrode array comprising:
a first electrode material; and
an insulating material, wherein the first electrode material and the insulating material are arranged in a spiral configuration.

2. The electrode array of claim 1, wherein a working electrode is formed from the first electrode material, and wherein the first electrode material comprises a material selected from the group consisting of glassy carbon, gold, platinum, palladium, nickel, silver, copper, lead, zinc, silver/carbon, and combinations thereof.

3. The electrode array of claim 1, wherein the first electrode material comprises a sheet.

4. The electrode array of claim 1, wherein the first electrode material comprises a mesh.

5. The electrode array of claim 1, wherein the first electrode material comprises a film.

6. The electrode array of claim 1, wherein the first electrode material comprises a wire.

7. The electrode array of claim 1, further comprising a second electrode material.

8. The electrode array of claim 7, further comprising a counter electrode formed from the second electrode material, wherein the first electrode material, the insulating material, and the second electrode material are arranged in a spiral configuration, and wherein the second electrode material is selected from the group consisting of glassy carbon, gold, platinum, palladium, nickel, silver, copper, lead, zinc, silver/carbon, and combinations thereof.

9. The electrode array of claim 7, wherein the second electrode material comprises a sheet.

10. The electrode array of claim 7, wherein the second electrode material comprises a mesh.

11. The electrode array of claim 7, wherein the second electrode material comprises a film.

12. The electrode array of claim 7, wherein the second electrode material comprises a wire.

13. The electrode array of claim 1, further comprising a reference electrode.

14. The electrode array of claim 13, wherein the first electrode material, the insulating material, and the third electrode material are arranged in a spiral configuration.

15. The electrode array of claim 13, wherein the third electrode material comprises a sheet.

16. The electrode array of claim 13, wherein the third electrode material comprises a mesh.

17. The electrode array of claim 13, wherein the third electrode material comprises a film.

18. The electrode array of claim 13, wherein the third electrode material comprises a wire.

19. The electrode array of claim 13, wherein the reference electrode is located at a center of the spiral configuration.

20. The electrode array of claim 1, further comprising a second electrode material and a third electrode material, wherein the first electrode material comprises a working electrode, wherein the second electrode material comprises a counter electrode, and wherein the third electrode material comprises a reference electrode.

21. The electrode array of claim 1 further comprising a second electrode material and a third electrode material, wherein the first electrode material comprises a first working electrode, wherein the second electrode material comprises a second working electrode, and wherein the third electrode material comprises a reference electrode.

22. The electrode array of claim 21, further comprising a reference electrode.

23. The electrode array of claim 1, further comprising a second electrode material and a third electrode material, wherein the first electrode material comprises a first working electrode, wherein the second electrode material comprises a second working electrode, and wherein the third electrode material comprises a counter electrode.

24. The electrode array of claim 1, wherein the insulating material comprises a silicone or a hydrogel.

25. The electrode array of claim 1, wherein the insulating material comprises a high oxygen soluble polymer.

26. The electrode array of claim 1, wherein the insulating material is selected from the group consisting of polyimide, polyester, polyurethane, perfluorinated polymer, polycarbonate, polyvinyl chloride, high-density polypropylene, low-density polypropylene, Parylene, epoxy, hydrogels, silicone, and mixtures thereof.

27. The electrode array of claim 1, wherein the insulating material comprises a thickness of from about 1 micron to about 1000 microns.

28. The electrode array of claim 1, wherein the insulating material comprises a thickness of from about 1 micron to about 100 microns.

29. The electrode array of claim 1, wherein the electrode array comprises a substantially planar surface.

30. The electrode array of claim 1, wherein the electrode array comprises a substantially curved surface.

31. The electrode array of claim 1, wherein the electrode array comprises a stepped surface.

32. The electrode array of claim 31, further comprising a polymer material formed atop at least one stepped surface.

33. The electrode array of claim 1, wherein the electrode array is flexible.

34. A method for manufacturing an electrode array for use in an electrochemical device, the method comprising:
forming a composite stack comprising an electrode material and an insulating material, wherein the insulating material is situated adjacent to the electrode material;
rolling the composite stack into a spiral roll; and
cutting away a portion of the spiral roll to form an electrode array.

35. The method of claim 34, wherein the composite stack is formed by adhering the electrode material to the insulating material.

36. The method of claim 34, wherein the electrode material is deposited on the insulating material by a method selected from the group consisting of thick film printing, vapor deposition, screen deposition, spray coating, roller coating, vacuum deposition, thin film deposition, sputtering, evaporation, spin coating, and combinations thereof.

37. The method of claim 34, wherein the electrode material comprises a working electrode, and wherein the electrode material is selected from the group consisting of glassy carbon, gold, platinum, palladium, nickel, silver, copper, lead, zinc, silver/carbon, and mixtures thereof.

38. The method of claim 34, wherein the electrode material comprises a sheet.

39. The method of claim 34, wherein the electrode material comprises a mesh.

40. The method of claim 34, wherein the electrode material comprises a film.

41. The method of claim 34, wherein the electrode material comprises a wire.

42. The method of claim 34, wherein the electrode material comprises a first electrode material and a second electrode material, wherein the second electrode material comprises a reference electrode material.

43. The method of claim 42, wherein the reference electrode material comprises a sheet.

44. The method of claim 42, wherein the reference electrode material comprises a mesh.

45. The method of claim 42, wherein the reference electrode material comprises a film.

46. The method of claim 42, wherein the reference electrode material comprises a wire.

47. The method of claim 34, wherein the insulating material comprises a polymer in which oxygen is soluble.

48. The method of claim 47, wherein the insulating material comprises a silicone or a hydrogel.

49. The method of claim 34, wherein the insulating material is selected from the group consisting of polyimide, polyester, polyurethane, perfluorinated polymer, polycarbonate, polyvinyl chloride, high-density polypropylene, low-density polypropylene, Parylene, epoxy, hydrogels, silicone, and mixtures thereof.

50. The method of claim 34, wherein the electrode material comprises one or more wires, and wherein the composite stack is formed by molding or flattening the wires into the insulating material, thereby forming an integrated layer.

51. The method of claim 34, wherein the electrode material comprises a first electrode material and a second electrode material, and wherein a thickness of the first electrode material is at least twice a thickness of the second electrode material.

52. The method of claim 34, wherein the insulating material comprises a thickness of from about 1 micron to about 1000 microns.

53. The method of claim 34, wherein the insulating material comprises a thickness of from about 1 micron to about 100 microns.

54. The of claim 34, wherein the composite stack comprises a first electrode material, a second electrode material, and a third electrode material; wherein the first electrode material comprises a first working electrode, wherein the second electrode material comprises a second working electrode, and wherein the third electrode material comprises a reference electrode.

55. The method of claim 34, wherein the composite stack comprises a first electrode material, and wherein the first electrode material comprises a working electrode.

56. The method of claim 55, further comprising:
providing a reference electrode.

57. The method for manufacturing the electrode array of claim 55, wherein the composite stack further comprises a second electrode material, wherein the second electrode material comprises a counter electrode.

58. The method of claim 57, further comprising:
providing a reference electrode.

59. The method of claim 57, wherein the composite stack further comprises a third electrode material, wherein the third electrode material comprises a reference electrode.

60. The method of claim 34, wherein the composite stack comprises a first electrode material comprising a first working electrode, a second electrode material comprising a second working electrode, and a third electrode material comprising a counter electrode.

61. The method of claim 60, further comprising:
providing a reference electrode.

62. The method of claim 34, wherein the step of rolling the composite stack comprises selectively rolling the electrode material and the insulating material on a rolling mandrel.

63. The method of claim 34, wherein the step of cutting away is selected from the group consisting of cutting away with a knife, cutting away with a water jet, cutting away with a laser, cutting away with a plasma arc, and cutting away with an oxyfuel.

64. The method of claim 34, wherein the composite stack comprises an elastomeric material, the method further comprising:
freezing the spiral roll, whereby the elastomeric material is hardened, wherein the step of freezing is conducted before the step of cutting away.

65. The method of claim 64, wherein the step of cutting away is selected from the group consisting of cutting away with a knife, cutting away with a water jet, cutting away with a laser, cutting away with a plasma arc, and cutting away with an oxyfuel.

66. The method of claim 34, wherein the step of cutting away a portion of the spiral roll comprises cutting along a plane perpendicular to a longitudinal axis of the spiral roll.

67. The method of claim 34, wherein the step of cutting away a portion of the spiral roll comprises cutting along a plane that is at an angle of less than 90 degrees to a longitudinal axis of the spiral roll.

68. The method of claim 34, wherein the step of cutting away a portion of the spiral roll comprises cutting along a longitudinal axis of the spiral roll.

69. The method of claim 34, wherein the step of cutting away a portion of the spiral roll comprises cutting fully across a diameter of the spiral roll.

70. The method of claim 34, wherein the step of cutting away a portion of the spiral roll comprises cutting partially across a diameter of the spiral roll.

71. The method of claim 34, further comprising the step of
post-processing the electrode array by subjecting at least one surface of the electrode array to machining, polishing, or shaping.

72. The method of claim 71, wherein the post-processing produces a non-planar surface on the electrode array.

73. The method of claim 34, further comprising the step of
post-processing the electrode array by etching away a portion of the electrode material, whereby an etched away portion is obtained.

74. The method of claim 73, further comprising the step of
filling the etched away portion with a polymer.

75. An electrode array manufactured according to the method of claim 34.

76. A biosensor comprising an electrode array manufactured according to the method of claim 34.

77. A biosensor comprising the electrode array according to claim 1.
